(19) United States
(12) Patent Application Publication
(10) Pub. No.: US 2023/0074991 A1
(43) Pub. Date: Mar. 9, 2023

(54) SUBSTRATE TREATING APPARATUS, SUBSTRATE TREATING EQUIPMENT, AND SUBSTRATE TREATING METHOD

(71) Applicant: SEMES CO., LTD., Chungcheongnam-do (KR)

(72) Inventors: Sung Chul JUNG, Chungcheongnam-do (KR); Sang Bok HAN, Chungcheongnam-do (KR)

(21) Appl. No.: 17/903,324

(22) Filed: Sep. 6, 2022

(30) Foreign Application Priority Data
Sep. 8, 2021 (KR) 10-2021-0119934
Aug. 12, 2022 (KR) 10-2022-0101051

(51) Int. Cl. G03F 7/20

(52) U.S. Cl. CPC G03F 7/7085; G03F 7/70825; G03F 7/70991

(57) ABSTRACT

An apparatus for treating a substrate includes a plurality of heat treatment chambers and a plurality of sensors that determine whether the plurality of heat treatment chambers are mounted. The number of the plurality of sensors corresponds to the number of the plurality of heat treatment chambers. The plurality of sensors are B contact sensors.

### CROSS-REFERENCE TO RELATED APPLICATIONS

A claim for priority under 35 U.S.C. § 119 is made to Korean Patent Application No. 10-2021-0119934 filed on Sep. 8, 2021 and Korean Patent Application No. 10-2022-0101051 filed on Aug. 12, 2022 in the Korean Intellectual Property Office, the entire contents of which are hereby incorporated by reference.

### BACKGROUND

Embodiments of the inventive concept described herein relate to a substrate treating apparatus, substrate treating equipment, and a substrate treating method, and more particularly, relate to a substrate treating apparatus and method for easily determining whether a heat treatment chamber is replaced.

Various processes, such as cleaning, deposition, photolithography, etching, ion implantation, and the like, are performed to manufacture semiconductor devices. Among these processes, the photolithography process includes a coating process of coating a surface of a substrate with a photosensitive liquid, such as photoresist, to form a film on the substrate, an exposure process of transferring a circuit pattern to the film formed on the substrate, and a developing process of selectively removing the film on the substrate in a region exposed to light or a region not exposed to light.

For example, the coating process may be performed in spinner equipment. The spinner equipment is equipped with a plurality of heat treatment chambers. When a heat treatment chamber is defective, the defective heat treatment chamber has to be disassembled, and a new heat treatment chamber has to be mounted, or when there is a modification item for a heat treatment chamber, the heat treatment chamber cannot be modified on the site, and therefore a new heat treatment chamber to which the modification item is applied has to be mounted.

The heat treatment chambers mounted in the spinner equipment may be frequently replaced. However, since the serial numbers of changed heat treatment chambers and the positions in which the changed heat treatment chambers are mounted are manually input, omission or an error may occur.

In particular, when control methods differ from one another depending on the types of the heat treatment chambers, software contains driving logic for each type and stores information about the types of the heat treatment chambers. In this case, if a user incorrectly inputs the information, malfunctions may occur.

FIGS. 1A and 1B are views illustrating heat treatment chambers in a substrate treating apparatus in the related art. Referring to FIG. 1A, although the heat treatment chambers 320 are assigned with unique serial numbers containing information such as production information, type, status of applied parts, the number of repairs, and the like, labels for the serial numbers that are attached to the respective heat treatment chambers can only be identified with the naked eyes. Referring to FIG. 1B, in order to allow equipment to read the serial numbers, devices (e.g., scanners or RF antennas) for reading the serial numbers need to be mounted in the respective positions in which the heat treatment chambers 320 are mounted, and therefore the equipment may be complicated.

### SUMMARY

Embodiments of the inventive concept provide a substrate treating apparatus, substrate treating equipment, and a substrate treating method for minimizing a user's tasks and mistakes when a heat treatment chamber is replaced.

The technical problems to be solved by the inventive concept are not limited to the aforementioned problems. Any other technical problems not mentioned herein will be clearly understood from the following description by those skilled in the art to which the inventive concept pertains.

According to an embodiment, an apparatus for treating a substrate includes a plurality of heat treatment chambers and a plurality of sensors that determine whether the plurality of heat treatment chambers are mounted.

According to an embodiment, the number of the plurality of sensors may correspond to the number of the plurality of heat treatment chambers.

According to an embodiment, the plurality of sensors may be B contact sensors.

According to an embodiment, the plurality of sensors may be turned off when the plurality of heat treatment chambers are mounted, and the plurality of sensors may be turned on when the plurality of heat treatment chambers are removed.

According to an embodiment, the apparatus may further include a controller that generates a signal for reading information of a heat treatment chamber being replaced, based on measurement results of the plurality of sensors.

According to an embodiment, the apparatus may further include first codes attached to the plurality of heat treatment chambers, respectively, and including information of the plurality of heat treatment chambers and second codes including information about positions to which the plurality of heat treatment chambers are attached.

According to an embodiment, when the controller generates the signal, the information of the heat treatment chamber being replaced may be scanned through a scanning device that recognizes the first codes and the second codes.

According to an embodiment, the controller and the plurality of heat treatment chambers may be connected through TO contacts.

According to an embodiment, equipment for treating a substrate includes a first substrate treating apparatus including a plurality of first heat treatment chambers and a second substrate treating apparatus including a plurality of second heat treatment chambers. The first substrate treating apparatus includes a plurality of first sensors that determine whether the plurality of first heat treatment chambers are mounted, and the second substrate treating apparatus includes a plurality of second sensors that determine whether the plurality of second heat treatment chambers are mounted. The equipment further includes a storage server that collects and stores entire information of the plurality of first and second heat treatment chambers included in the first and second substrate treating apparatuses.

According to an embodiment, information of a first heat treatment chamber or a second heat treatment chamber being replaced may be scanned and stored in the storage server.

According to an embodiment, a method for treating a substrate using a plurality of heat treatment chambers includes determining whether a plurality of sensors that determine whether the plurality of heat treatment chambers are mounted are turned on or off and generating a signal for reading information of a heat treatment chamber corresponding to a turned-on sensor among the plurality of sensors.

According to an embodiment, the method may further include scanning the information of the corresponding heat treatment chamber and position information thereof depending on the signal.

According to an embodiment, the method may further include storing the scanned information of the heat treatment chamber and the scanned position information thereof in a server.

According to an embodiment, the plurality of sensors may be B contact sensors.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIGS. 1A and 1B are views illustrating heat treatment chambers in a substrate treating apparatus in the related art;

FIG. 2 is a view for describing a configuration of a substrate treating apparatus according to an embodiment of the inventive concept;

FIG. 3 is a view for describing an operation configuration of a conventional sensor;

FIG. 4 is a view for describing an operation configuration of a sensor according to an embodiment of the inventive concept;

FIG. 5 is a view for describing a configuration of a substrate treating apparatus according to another embodiment of the inventive concept;

FIG. 6 is a view illustrating substrate treating equipment according to an embodiment of the inventive concept;

FIG. 7 is a view for describing a connection between a controller and a heat treatment chamber according to an embodiment of the inventive concept;

FIG. 8 is a schematic perspective view illustrating a substrate treating apparatus according to an embodiment of the inventive concept;

FIG. 9 is a sectional view illustrating a coating block and a developing block of the substrate treating apparatus of FIG. 8;

FIG. 10 is a plan view of the substrate treating apparatus of FIG. 8;

FIG. 11 is a schematic plan view illustrating a transfer robot of FIG. 10;

FIG. 12 is a schematic plan view illustrating one example of heat treatment chambers of FIG. 10; and

FIG. 13 is a front view of the heat treatment chamber of FIG. 12.

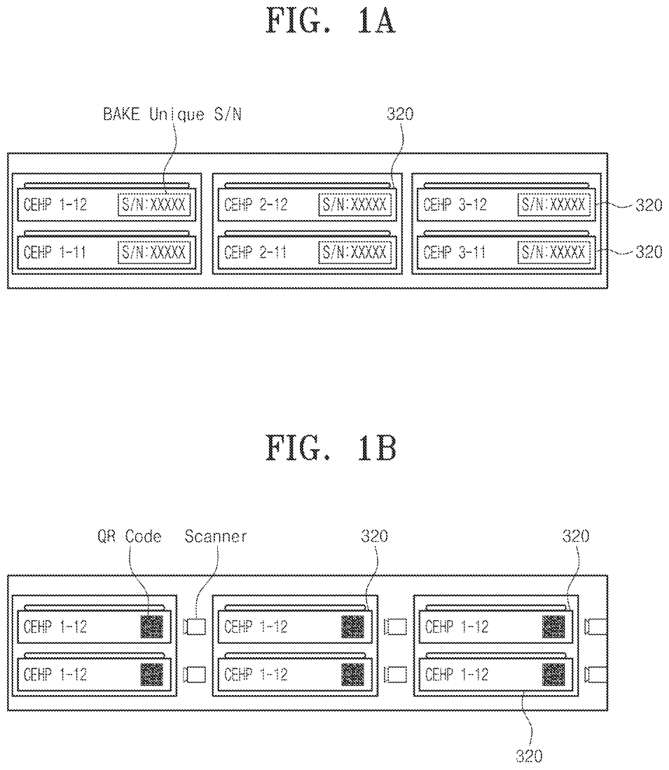

### DETAILED DESCRIPTION

Hereinafter, embodiments of the inventive concept will be described in detail with reference to the accompanying drawings such that those skilled in the art to which the inventive concept pertains can readily carry out the inventive concept. However, the inventive concept may be implemented in various different forms and is not limited to the embodiments described herein. Furthermore, in describing the embodiments of the inventive concept, detailed descriptions related to well-known functions or configurations will be omitted when they may make subject matters of the inventive concept unnecessarily obscure. In addition, components performing similar functions and operations are provided with identical reference numerals throughout the accompanying drawings.

The terms “include” and “comprise” in the specification are “open type” expressions just to say that the corresponding components exist and, unless specifically described to the contrary, do not exclude but may include additional components. Specifically, it should be understood that the terms “include”, “comprise”, and “have”, when used herein, specify the presence of stated features, integers, steps, operations, components, and/or parts, but do not preclude the presence or addition of one or more other features, integers, steps, operations, components, parts, and/or groups thereof.

The terms of a singular form may include plural forms unless otherwise specified. Furthermore, in the drawings, the shapes and dimensions of components may be exaggerated for clarity of illustration.

Hereinafter, embodiments of the inventive concept will be described in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. In the drawings, the dimensions of components are exaggerated for clarity of illustration.

To minimize a user's tasks and mistakes when a heat treatment chamber 320 is replaced, a sensor 330 for determining whether the heat treatment chamber 320 is mounted may be mounted in a mounting position of the heat treatment chamber 320, and the inventive concept may recognize, through a change of state of the sensor 330, whether the heat treatment chamber 320 is replaced and may alert the user to registration of the serial number of the heat treatment chamber 320 being replaced, thereby preventing the user from omitting the registration of the serial number. In the related art, readers have to be mounted to read the serial numbers of respective heat treatment chambers 320, and when a person directly reads the serial numbers with one reader, omission is likely to occur.

According to an embodiment, the sensor 330 mounted on the heat treatment chamber 320 may be implemented with a B contact sensor. Accordingly, the sensor 330 may be turned on only when the heat treatment chamber 320 is replaced, and thus whether the heat treatment chamber 320 is replaced may be efficiently determined. Furthermore, the serial number of the heat treatment chamber 320 may be attached in the form of a QR code such that the user is able to scan the serial number. In addition, two QR codes may be attached such that the position in which the heat treatment chamber 320 is mounted and the serial number thereof are able to be read at the same time, and thus the user may simultaneously recognize where the heat treatment chamber 320 is mounted.

Hereinafter, embodiments of the inventive concept will be described in more detail with reference to the accompanying drawings.

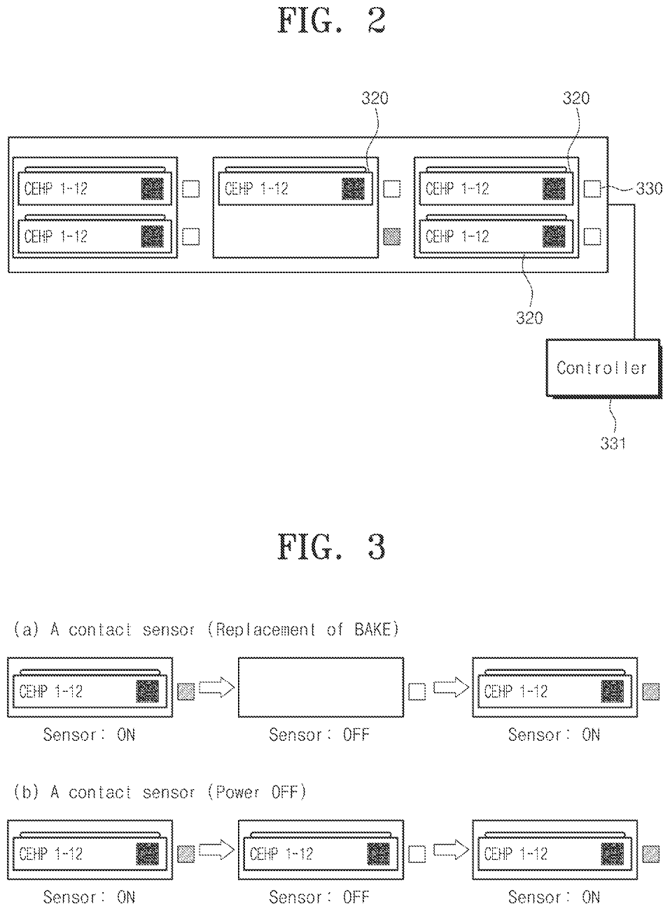

FIG. 2 is a view for describing a configuration of a substrate treating apparatus according to an embodiment of the inventive concept.

Referring to FIG. 2, the substrate treating apparatus may include a plurality of heat treatment chambers 320. According to an embodiment, the substrate treating apparatus may include a plurality of sensors 330 capable of determining whether the heat treatment chambers 320 are mounted.

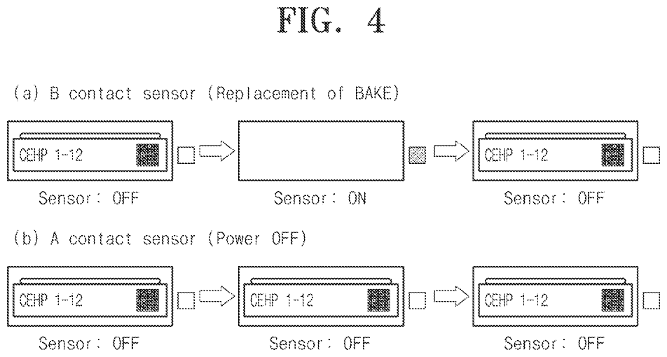

As many sensors 330 as the heat treatment chambers 320 may be provided. According to an embodiment, as many sensors 330 as mounting cases or mounting positions in which the heat treatment chambers 320 are mounted may be provided. In this specification, the cases in which the heat treatment chambers 320 are mounted may be provided, and placing the heat treatment chambers 320 in predetermined mounting positions without the cases may be regarded as mounting. Hereinafter, the latter case will be described. Referring to FIG. 2, six mounting positions in which the heat treatment chambers 320 are able to be mounted and six sensors 330 may be provided. According to an embodiment, the sensors 330 may be implemented with B contact sensors. According to an embodiment, the sensors 330 may be turned off when the heat treatment chambers 320 are mounted and may be turned on when the heat treatment chambers 320 are removed. Here, the removal of the heat treatment chambers 320 may mean that the heat treatment chambers 320 are out of the mounting positions. Operating characteristics of the sensors 330 will be described below in more detail with reference to FIGS. 3 and 4.

A controller 331 may generate a signal for reading information of a heat treatment chamber 320 being replaced, based on measurement results of the plurality of sensors 330. According to an embodiment, the B contact sensors for sensing the heat treatment chambers 320 may be mounted in the mounting positions of the heat treatment chambers 320, and the controller 331 may recognize replacement of a heat treatment chamber 320 through a change of state of a sensor 330 and may display, on a user interface (UI), the fact that the serial number of the heat treatment chamber 320 is required to be read. According to an embodiment, so as not to omit registration of the serial number (SN), the controller 331 may output a message related thereto.

FIG. 2 illustrates a situation in which a heat treatment chamber 320 located in a lower middle position is replaced. Referring to FIG. 2, when the heat treatment chamber 320 is removed so that a corresponding slot is empty, a corresponding sensor 330 may be turned on to rapidly notify of the replacement of the heat treatment chamber 320 and may transfer the notification to the controller 331 to allow the controller 331 to read information of the heat treatment chamber 320 being replaced.

According to the embodiment illustrated in FIG. 2, when the heat treatment chamber 320 is mounted, the sensor 330 may be turned off, and when the heat treatment chamber 320 is not mounted, the sensor 330 may be turned on. That is, when the heat treatment chamber 320 is replaced, the state of the sensor 330 may be changed from a turned-off state to a turned-on state and then from the turned-on state to the turned-off state. The controller 331 may detect the change of state of the sensor 330 and may display, on a display or UI connected thereto, a message indicating that scanner reading is required.

FIG. 3 is a view for describing an operation configuration of a conventional sensor.

FIG. 3 illustrates a case in which an A contact sensor is used as the conventional sensor.

In the case of using the A contact sensor, the sensor may be turned on when a heat treatment chamber 320 is mounted and may be turned off when the heat treatment chamber 320 is not mounted. However, in this case, the sensor may be turned off even when the heat treatment chamber 320 itself or a substrate treating apparatus including the heat treatment chamber 320 is powered off, and therefore replacement of the chamber and the power-off of the chamber may not be distinguished from each other.

FIG. 4 is a view for describing an operation configuration of a sensor 330 according to an embodiment of the inventive concept.

Referring to FIG. 4, a B contact sensor is used as the sensor 330 according to the inventive concept.

In the case of using the B contact sensor, the sensor may be turned off when a heat treatment chamber 320 is mounted and may be turned on when the heat treatment chamber 320 is not mounted. In the case of using the B contact sensor, the sensor may be turned off regardless of whether the heat treatment chamber 320 itself or a substrate treating apparatus including the heat treatment chamber 320 is powered on or off, and thus the power off may be prevented from being incorrectly recognized as release of the heat treatment chamber 320.

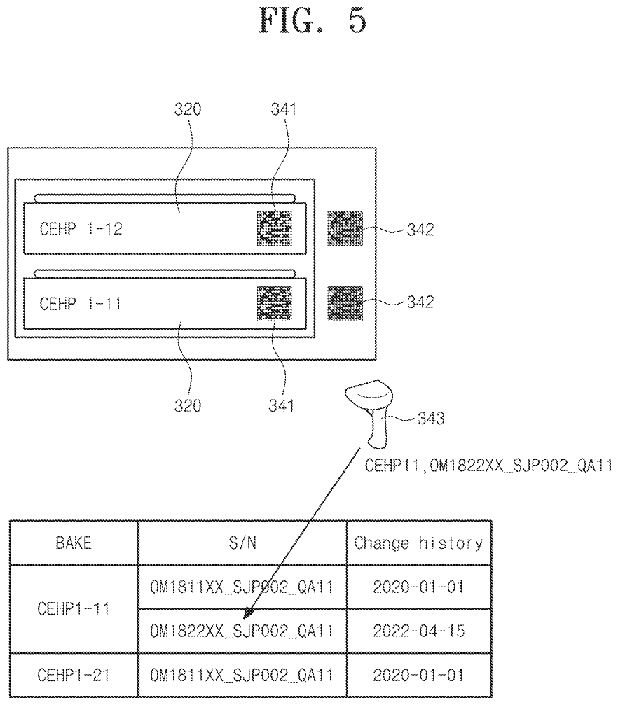

FIG. 5 is a view for describing a configuration of a substrate treating apparatus according to another embodiment of the inventive concept.

Referring to FIG. 5, an embodiment including first codes 341 and second codes 342 is disclosed. The first codes 341 may be attached to a plurality of heat treatment chambers 320, respectively, and may include information of the heat treatment chambers 320. The second codes 342 may include information about positions to which the heat treatment chambers 320 are attached. The number of first codes 341 and the number of second codes 342 may correspond to the number of heat treatment chambers 320 or the number of mounting positions of the heat treatment chambers 320. According to an embodiment, the first codes 341 and the second codes 342 may be QR codes. However, without being limited thereto, the first codes 341 and the second codes 342 may include various forms of codes capable of including information.

In the related art, position information of a heat treatment chamber 320 is not included in the serial number of the heat treatment chamber 320, and therefore the serial number has to be changed every time the position of the heat treatment chamber 320 is changed.

However, in the inventive concept, the second codes 342 including the information about the positions to which the heat treatment chambers 320 are attached may be additionally provided, and the two QR codes of each of the heat treatment chambers 320 may be simultaneously read by a scanning device 343. Accordingly, the serial number and the mounting position of the heat treatment chamber 320 may be determined by using only the one scanning device 343 without separately mounting scanning devices 343 on the heat treatment chambers 320 included in the substrate treating apparatus. When a replacement signal of each of the heat treatment chambers 320 is generated, a controller 331 may scan information of the heat treatment chamber 320 being replaced, through the scanning device 343 capable of recognizing the first codes 341 and the second codes 342. The scanning device 343 may be a scanner capable of recognizing information of the first codes 341 and the second codes 342.

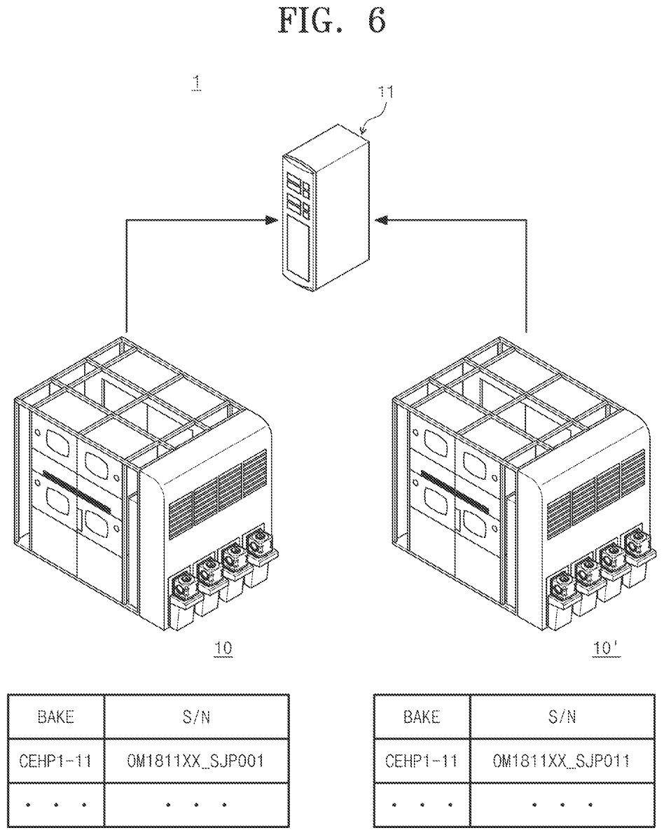

FIG. 6 is a view illustrating substrate treating equipment according to an embodiment of the inventive concept.

According to an embodiment, the substrate treating equipment 1 may include a first substrate treating apparatus 10 including a plurality of first heat treatment chambers 320 and a second substrate treating apparatus 10′ including a plurality of second heat treatment chambers 320.

The first substrate treating apparatus 10 may include a plurality of first sensors capable of determining whether the first heat treatment chambers are mounted, and the second substrate treating apparatus 10′ may include a plurality of second sensors capable of determining whether the second heat treatment chambers are mounted. The substrate treating equipment 1 may further include a storage server 11 that collects and stores entire information of the first and second heat treatment chambers included in the first and second substrate treating apparatuses 10 and 10′.

Repetitive descriptions of the heat treatment chambers 320, the sensors 330, and controllers 331 of the substrate treating apparatuses 10 and 10′ identical to ones given with reference to FIGS. 2 to 5 will be omitted.

Referring to FIG. 6, the storage server 11 that stores the information of the heat treatment chambers 320 included in the substrate treating apparatuses 10 and 10′ is disclosed. When a first heat treatment chamber or a second heat treatment chamber is replaced, the storage server 11 may scan and store corresponding information.

According to an embodiment, when a heat treatment chamber installed in one of the substrate treating apparatuses is defective and replaced with a new heat treatment chamber, the defective heat treatment chamber may be mounted in a substrate treating apparatus rather than the existing substrate treating apparatus after repaired. Referring to FIG. 6, it may be possible to identify movement histories of the heat treatment chambers by gathering information collected by the storage server 11 that collects the information of the heat treatment chambers included in all of the substrate treating apparatuses in the line.

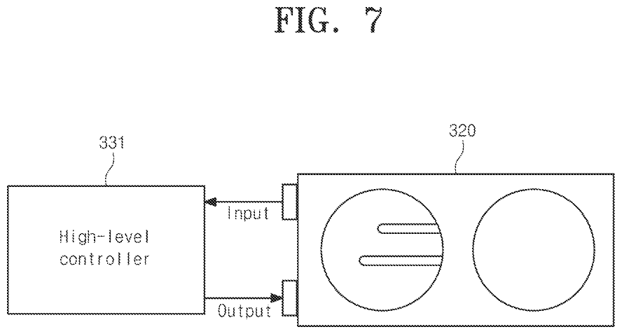

FIG. 7 is a view for describing a connection between a controller 331 and a heat treatment chamber 320 according to an embodiment of the inventive concept. According to an embodiment, the controller 331 and the heat treatment chamber 320 may be connected through IO contacts. That is, according to the inventive concept, simple type information of the heat treatment chamber 320 rather than complex information such as serial number information may be automatically recognized through the IO contacts. The controller 331 may operate the heat treatment chamber 320 through the IO contacts of the heat treatment chamber 320. According to an embodiment, the type information of the heat treatment chamber 320 may be added to the IO contacts. When the heat treatment chamber 320 is replaced, the controller 331 may identify corresponding IO and may perform control according to the type of the heat treatment chamber 320. According to an embodiment, the controller 331 may be a high-level controller. That is, according to the inventive concept, a database that manages a change history may be constructed by recording and storing, in a high-level controller of a substrate treating apparatus, detail information (e.g., the serial number) of the heat treatment chamber 320 mounted in the substrate treating apparatus. Furthermore, IO representing the type information of the heat treatment chamber 320 may be added to the IO of the heat treatment chamber 320. High-level SW may read the corresponding IO, and SW processing suitable for the type of the heat treatment chamber 320 may be automatically performed.

According to an embodiment, when the heat treatment chamber 320 is replaced, control may be performed to identify the corresponding IO and change parameters and control logic suitable for the type of the heat treatment chamber 320.

Hereinafter, a method of treating a substrate using a plurality of heat treatment chambers 320 according to another embodiment of the inventive concept is disclosed.

The method may include a step of determining whether a plurality of sensors 330 capable of determining whether the plurality of heat treatment chambers 320 are mounted or not are turned on or off; and a step of generating a signal for reading information of a heat treatment chamber 320 corresponding to a turned-on sensor 330 among the plurality of sensors 330. The method may further include a step of scanning the information of the corresponding heat treatment chamber 320 and position information thereof depending on the generated signal. In this case, the scanning may be performed through a first code 341 and a second code 342. The method may further include a step of storing the scanned information of the heat treatment chamber 320 and the scanned position information thereof in a server. Accordingly, the information of the heat treatment chamber 320 being replaced and the position information thereof may be stored in the storage server and may be efficiently managed.

An apparatus of this embodiment may be used to perform a photolithography process on a circular substrate. In particular, the apparatus of this embodiment may be connected to an exposure apparatus and may be used to perform a coating process of coating a substrate with photoresist. However, without being limited thereto, the spirit and scope of the inventive concept may be applied to various types of processes of supplying processing liquids other than photoresist to rotating substrates. For example, the processing liquids may include a developing solution, a chemical, a rinsing solution, and an organic solvent. Furthermore, the spirit and scope of the inventive concept may be applied to a process of rotating a substrate without supplying a processing liquid while evacuating a space in which the substrate is provided.

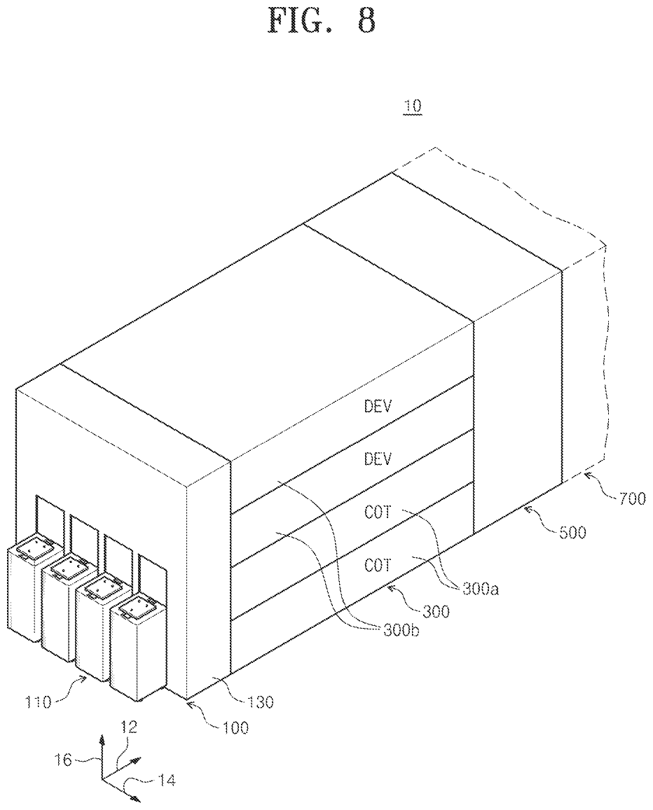

Hereinafter, embodiments of the inventive concept will be described with reference to FIGS. 8 to 13.

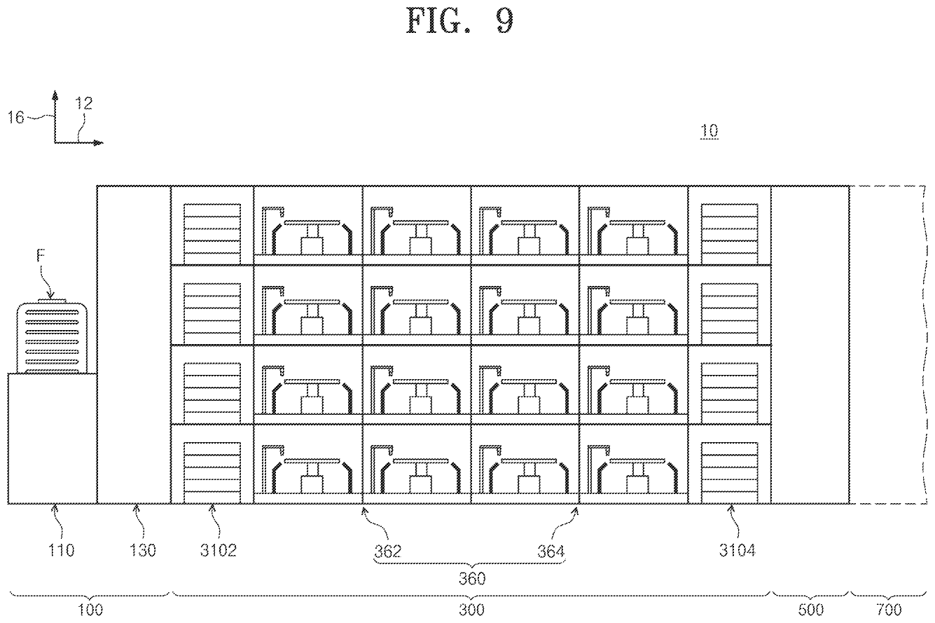

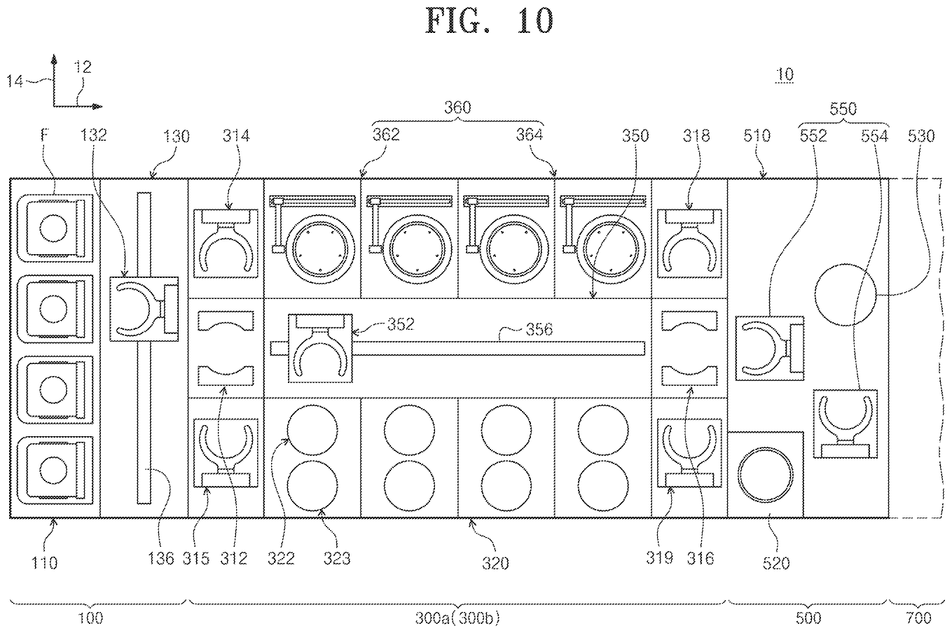

FIG. 8 is a schematic perspective view illustrating a substrate treating apparatus according to an embodiment of the inventive concept. FIG. 9 is a sectional view illustrating a coating block and a developing block of the substrate treating apparatus of FIG. 8. FIG. 10 is a plan view of the substrate treating apparatus of FIG. 8.

Referring to FIGS. 8 to 10, the substrate treating apparatus 10 according to an embodiment of the inventive concept includes an index module 100, a processing module 300, and an interface module 500. According to an embodiment, the index module 100, the processing module 300, and the interface module 500 are sequentially arranged in a row. Hereinafter, a direction in which the index module 100, the processing module 300, and the interface module 500 are arranged is referred to as a first direction 12, a direction perpendicular to the first direction 12 when viewed from above is referred to as a second direction 14, and a direction perpendicular to both the first direction 12 and the second direction 14 is referred to as a third direction 16.

The index module 100 transfers substrates W from a carrier F having the substrates W received therein to the processing module 300 and places the treated substrates W in the carrier F. The index module 100 is disposed such that the lengthwise direction thereof is parallel to the second direction 14. The index module 100 has a load port 110 and an index frame 130. The load port 110 is located on the opposite side to the processing module 300 with respect to the index frame 130. The carrier F having the substrates W received therein is placed on the load port 110. A plurality of load ports 110 may be provided. The plurality of load ports 110 may be arranged in the second direction 14.

An airtight carrier F, such as a front open unified pod (FOUP), may be used as the carrier F. The carrier F may be placed on the load port 110 by a transfer unit (not illustrated), such as an overhead transfer, an overhead conveyor, or an automatic guided vehicle, or by an operator.

An index robot 132 is provided in the index frame 130. A guide rail 136, the lengthwise direction of which is parallel to the second direction 14, is provided in the index frame 130. The index robot 132 is movable on the guide rail 136. The index robot 132 includes a hand on which a substrate W is placed. The hand is movable forward and backward, rotatable about an axis facing the third direction 16, and movable in the third direction 16.

The processing module 300 may perform a coating process and a developing process on the substrates W. The processing module 300 may receive the substrates W accommodated in the carrier F and may perform a substrate treating process on the substrates W. The processing module 300 has the coating block 300a and the developing block 300b. The coating block 300a performs the coating process on the substrates W, and the developing block 300b performs the developing process on the substrates W. A plurality of coating blocks 300a may be provided. The coating blocks 300a may be stacked one above another. A plurality of developing blocks 300b may be provided. The developing blocks 300b may be stacked one above another. According to the embodiment of FIG. 8, two coating blocks 300a and two developing blocks 300b are provided. The coating blocks 300a may be disposed under the developing blocks 300b. According to an embodiment, the two coating blocks 300a may perform the same process and may have the same structure. Furthermore, the two developing blocks 300b may perform the same process and may have the same structure.

Referring to FIG. 10, the coating block 300a has heat treatment chambers 320, a transfer chamber 350, liquid processing chambers 360, and buffer chambers 312 and 316. The heat treatment chambers 320 perform a heat treatment process on the substrates W. The heat treatment process may include a cooling process and a heating process. The liquid processing chambers 360 form liquid films on the substrates W by supplying a liquid onto the substrates W. The liquid films may be photoresist films or anti-reflection films. The transfer chamber 350 transfers the substrates W between the heat treatment chambers 320 and the liquid processing chambers 360 in the coating block 300a.

The transfer chamber 350 is disposed such that the lengthwise direction thereof is parallel to the first direction 12. A transfer robot 352 is provided in the transfer chamber 350. The transfer robot 352 transfers the substrates W between the heat treatment chambers 320, the liquid processing chambers 360, and the buffer chambers 312 and 316. According to an embodiment, the transfer robot 352 has a hand 354 on which a substrate W is placed. The hand 354 is movable forward and backward, rotatable about an axis facing the third direction 16, and movable in the third direction 16. A guide rail 356, the lengthwise direction of which is parallel to the first direction 12, is provided in the transfer chamber 350, and the transfer robot 352 is movable on the guide rail 356.

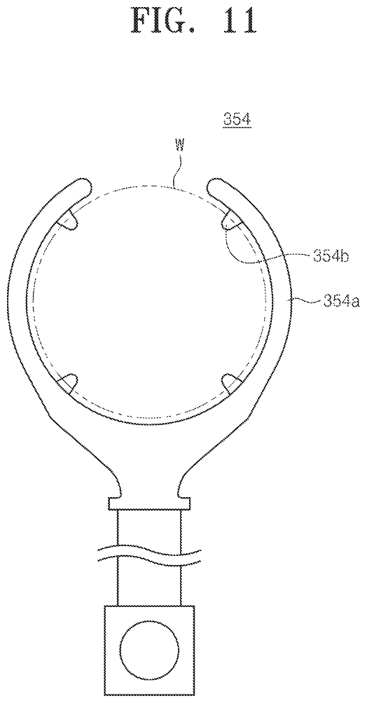

FIG. 11 is a view illustrating one example of the hand 354 of the transfer robot 352. Referring to FIG. 11, the hand 354 has a base 354a and a support protrusion 354b. The base 354a may have an annular ring shape, the circumference of which is partially curved. The base 354a has an inner diameter greater than the diameter of the substrate W. The support protrusion 354b extends inward from the base 354a. A plurality of support protrusions 354b may be provided. The support protrusions 354b support an edge region of the substrate W. According to an embodiment, four support protrusions 354b may be provided at equal intervals.

A plurality of heat treatment chambers 320 are provided. The heat treatment chambers 320 are arranged in the first direction 12. The heat treatment chambers 320 are located on one side of the transfer chamber 350.

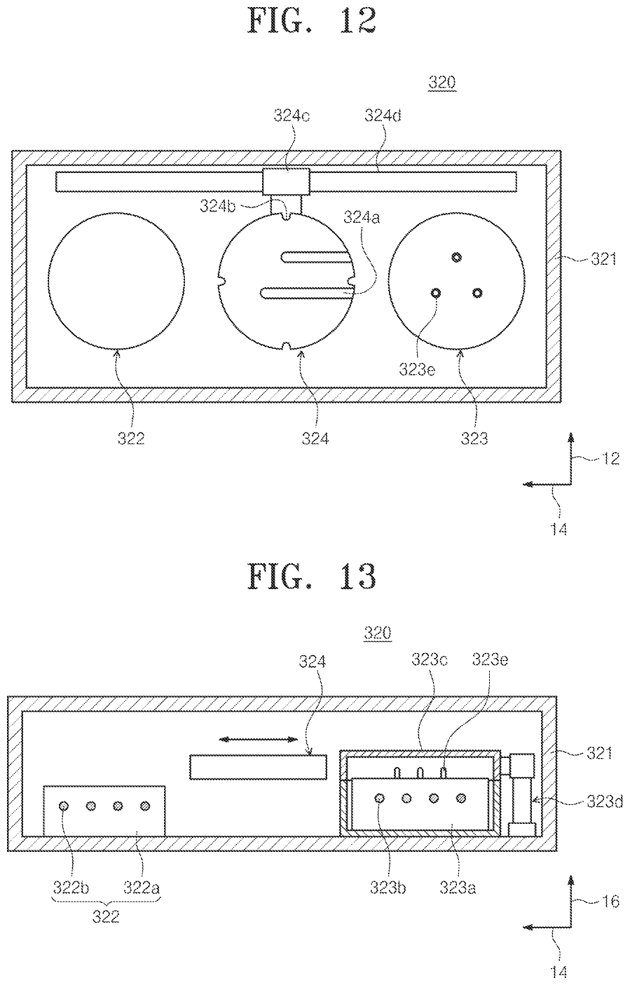

FIG. 12 is a schematic plan view illustrating one example of the heat treatment chambers of FIG. 10, and FIG. 13 is a front view of the heat treatment chamber of FIG. 12.

Referring to FIGS. 12 and 13, the heat treatment chamber 320 has a housing 321, a cooling unit 322, a heating unit 323, and a transfer plate 324.

The housing 321 has a substantially rectangular parallelepiped shape. The housing 321 has, in a sidewall thereof, an entrance/exit opening (not illustrated) through which a substrate W enters and exits the housing 321. The entrance/exit opening may remain open. A door (not illustrated) may be provided to selectively open and close the entrance/exit opening. The cooling unit 322, the heating unit 323, and the transfer plate 324 are provided in the housing 321. The cooling unit 322 and the heating unit 323 are arranged in the second direction 14. According to an embodiment, the cooling unit 322 may be located closer to the transfer chamber 350 than the heating unit 323.

The cooling unit 322 has a cooling plate 322a. The cooling plate 322a may have a substantially circular shape when viewed from above. A cooling member 322b is provided inside the cooling plate 322a. According to an embodiment, the cooling member 322b may be formed inside the cooling plate 322a and may serve as a fluid channel through which a cooling fluid flows.

The heating unit 323 has a heating plate 323a, a cover 323c, and a heater 323b. The heating plate 323a has a substantially circular shape when viewed from above. The heating plate 323a has a larger diameter than the substrate W. The heater 323b is installed inside the heating plate 323a. The heater 323b may be implemented with a resistance heating element to which an electric current is applied. The heating plate 323a has lift pins 323e vertically movable in the third direction 16. The lift pins 323e receive the substrate W from a transfer unit outside the heating unit 323 and lay the substrate W down on the heating plate 323a, or raise the substrate W off the heating plate 323a and transfer the substrate W to the transfer unit outside the heating unit 323. According to an embodiment, three lift pins 323e may be provided. The cover 323c has a space therein, which is open at the bottom.

The cover 323c is located over the heating plate 323a and is vertically moved by an actuator 323d. A space that the cover 323c is moved to form together with the heating plate 323a serves as a heating space in which the substrate W is heated.

The transfer plate 324 has a substantially circular plate shape and has a diameter corresponding to that of the substrate W. The transfer plate 324 has notches 324b formed at the edge thereof. The notches 324 may have a shape corresponding to the support protrusions 354b formed on the hand 354 of the transfer robot 352 described above. Furthermore, as many notches 324b as the support protrusions 354b formed on the hand 354 are formed in positions corresponding to the support protrusions 354b. The substrate W is transferred between the hand 354 and the transfer plate 324 when the vertical positions of the hand 354 and the transfer plate 324 aligned with each other in the up/down direction are changed. The transfer plate 324 may be mounted on a guide rail 324d and may be moved between a first region 3212 and a second region 3214 along the guide rail 324d by an actuator 324c. The transfer plate 324 has a plurality of guide grooves 324a in a slit shape. The guide grooves 324a extend inward from the edge of the transfer plate 324. The lengthwise direction of the guide grooves 324a is parallel to the second direction 14, and the guide grooves 324a are spaced apart from each other in the first direction 12. The guide grooves 324a prevent interference between the transfer plate 324 and the lift pins 323e when the substrate W is transferred between the transfer plate 324 and the heating unit 323.

The substrate W is cooled in a state in which the transfer plate 324 having the substrate W placed thereon is brought into contact with the cooling plate 322a. For efficient heat transfer between the cooling plate 322a and the substrate W, the transfer plate 324 is formed of a material having high heat conductivity. According to an embodiment, the transfer plate 324 may be formed of a metallic material.

The heating units 323 provided in some of the heat treatment chambers 320 may improve adhesion of photoresist to the substrate W by supplying a gas while heating the substrate W. According to an embodiment, the gas may be a hexamethyldisilane (HMDS) gas.

A plurality of liquid processing chambers 360 are provided. Some of the liquid processing chambers 360 may be stacked one above another. The liquid processing chambers 360 are disposed on an opposite side of the transfer chamber 350. The liquid processing chambers 360 are arranged side by side in the first direction 12. Some of the liquid processing chambers 360 are located adjacent to the index module 100. Hereinafter, the liquid processing chambers 360 located adjacent to the index module 100 are referred to as front liquid processing chambers 362. Other liquid processing chambers 360 are located adjacent to the interface module 500. Hereinafter, the liquid processing chambers 360 located adjacent to the interface module 500 are referred to as rear liquid processing chambers 364.

Each of the front liquid processing chambers 362 applies a first liquid to a substrate W, and each of the rear liquid processing chambers 364 applies a second liquid to the substrate W. The first liquid and the second liquid may be different types of liquids. According to an embodiment, the first liquid is an anti-reflection film, and the second liquid is photoresist. The photoresist may be applied to the substrate W coated with the anti-reflection film. Selectively, the first liquid may be photoresist, and the second liquid may be an anti-reflection film. In this case, the anti-reflection film may be applied to the substrate W coated with the photoresist. Selectively, the first liquid and the second liquid may be of the same type. Both the first liquid and the second liquid may be photoresist.

The developing block 300b has the same structure as the coating block 300a, and a liquid processing chamber provided in the developing block 300b supplies a developing solution onto a substrate.

The interface module 500 connects the processing module 300 with an external exposure apparatus 700. The interface module 500 has an interface frame 510, an additional process chamber 520, an interface buffer 530, and an interface robot 550.

The interface frame 510 may have, at the top thereof, a fan filter unit that forms a downward air flow in the interface frame 510. The additional process chamber 520, the interface buffer 530, and the interface robot 550 are disposed in the interface frame 510. The additional process chamber 520 may perform a predetermined additional process before a substrate W treated in the coating block 300a is transferred to the exposure apparatus 700. Selectively, the additional process chamber 520 may perform a predetermined additional process before the substrate W treated in the exposure apparatus 700 is transferred to the developing block 300b. According to an embodiment, the additional process may be an edge exposing process of exposing an edge region of the substrate W to light, a top-side cleaning process of cleaning the top side of the substrate W, or a backside cleaning process of cleaning the backside of the substrate W. A plurality of additional process chambers 520 may be provided. The additional process chambers 520 may be stacked one above another. The additional process chambers 520 may all perform the same process. Selectively, some of the additional process chambers 520 may perform different processes.

The interface buffer 530 provides a space in which the substrate W transferred between the coating block 300a, the additional process chambers 520, the exposure apparatus 700, and the developing block 300b temporarily stays while being transferred. A plurality of interface buffers 530 may be provided. The plurality of interface buffers 530 may be stacked one above another.

According to an embodiment, the additional process chambers 520 may be disposed on one side of an extension line facing the lengthwise direction of the transfer chamber 350, and the interface buffers 530 may be disposed on an opposite side of the extension line.

The interface robot 550 transfers the substrate W between the coating block 300a, the additional process chambers 520, the exposure apparatus 700, and the developing block 300b. The interface robot 550 may have a transfer hand to transfer the substrate W. The interface robot 550 may be implemented with one or more robots. According to an embodiment, the interface robot 550 has a first robot 552 and a second robot 554. The first robot 552 may transfer the substrate W between the coating block 300a, the additional process chambers 520, and the interface buffers 530. The second robot 554 may transfer the substrate W between the interface buffers 530 and the exposure apparatus 700 and may transfer the substrate W between the interface buffers 530 and the developing block 300b.

The first robot 552 and the second robot 554 each include a hand on which the substrate W is placed, and the hand is movable forward and backward, rotatable about an axis parallel to the third direction 16, and movable in the third direction 16.

As described above, according to the inventive concept, the substrate treating apparatus, the substrate treating equipment, and the substrate treating method may minimize a user's tasks and mistakes when a heat treatment chamber is replaced.

Effects of the inventive concept are not limited to the above-described effects. Any other effects not mentioned herein may be clearly understood from this specification and the accompanying drawings by those skilled in the art to which the inventive concept pertains.

Although the embodiments of the inventive concept have been described above, it should be understood that the embodiments are provided to help with comprehension of the inventive concept and are not intended to limit the scope of the inventive concept and that various modifications and equivalent embodiments can be made without departing from the spirit and scope of the inventive concept. The drawings provided in the inventive concept are only drawings of the optimal embodiments of the inventive concept. The scope of the inventive concept should be determined by the technical idea of the claims, and it should be understood that the scope of the inventive concept is not limited to the literal description of the claims, but actually extends to the category of equivalents of technical value.

While the inventive concept has been described with reference to embodiments, it will be apparent to those skilled in the art that various changes and modifications may be made without departing from the spirit and scope of the inventive concept. Therefore, it should be understood that the above embodiments are not limiting, but illustrative.

1. An apparatus for treating a substrate, the apparatus comprising:
a plurality of heat treatment chambers; and
a plurality of sensors configured to determine whether the plurality of heat treatment chambers are mounted.

2. The apparatus of claim 1, wherein the number of the plurality of sensors corresponds to the number of the plurality of heat treatment chambers.

3. The apparatus of claim 2, wherein the plurality of sensors are B contact sensors.

4. The apparatus of claim 3, wherein the plurality of sensors are turned off when the plurality of heat treatment chambers are mounted, and the plurality of sensors are turned on when the plurality of heat treatment chambers are removed.

5. The apparatus of claim 3, further comprising:
a controller configured to generate a signal for reading information of a heat treatment chamber being replaced, based on measurement results of the plurality of sensors.

6. The apparatus of claim 5, further comprising:
first codes attached to the plurality of heat treatment chambers, respectively, and including information of the plurality of heat treatment chambers; and
second codes including information about positions to which the plurality of heat treatment chambers are attached.

7. The apparatus of claim 6, wherein when the controller generates the signal, the information of the heat treatment chamber being replaced is scanned through a scanning device configured to recognize the first codes and the second codes.

8. The apparatus of claim 5, wherein the controller and the plurality of heat treatment chambers are connected through TO contacts.

9. Equipment for treating a substrate, the equipment comprising:
a first substrate treating apparatus including a plurality of first heat treatment chambers; and
a second substrate treating apparatus including a plurality of second heat treatment chambers,
wherein the first substrate treating apparatus includes a plurality of first sensors configured to determine whether the plurality of first heat treatment chambers are mounted,
wherein the second substrate treating apparatus includes a plurality of second sensors configured to determine whether the plurality of second heat treatment chambers are mounted, and
wherein the equipment further comprises a storage server configured to collect and store entire information of the plurality of first and second heat treatment chambers included in the first and second substrate treating apparatuses.

10. The equipment of claim 9, wherein the number of the plurality of first sensors corresponds to the number of the plurality of first heat treatment chambers, and
wherein the number of the plurality of second sensors corresponds to the number of the plurality of second heat treatment chambers.

11. The equipment of claim 10, wherein the plurality of first sensors and the plurality of second sensors are B contact sensors.

12. The equipment of claim 11, wherein the first substrate treating apparatus further includes a first controller configured to generate a first signal for reading information of a first heat treatment chamber being replaced, based on measurement results of the plurality of first sensors, and
wherein the second substrate treating apparatus further includes a second controller configured to generate a second signal for reading information of a second heat treatment chamber being replaced, based on measurement results of the plurality of second sensors.

13. The equipment of claim 12, wherein the first substrate treating apparatus further includes:
first codes attached to the plurality of first heat treatment chambers, respectively, and including information of the plurality of first heat treatment chambers; and
second codes including information about positions to which the plurality of first heat treatment chambers are attached, and
wherein the second substrate treating apparatus further includes:
first codes attached to the plurality of second heat treatment chambers, respectively, and including information of the plurality of second heat treatment chambers; and
second codes including information about positions to which the plurality of second heat treatment chambers are attached.

14. The equipment of claim 13, wherein when the first controller generates the first signal or the second controller generates the second signal, the information of the first heat treatment chamber or the second heat treatment chamber being replaced is scanned through a scanning device configured to recognize the first codes and the second codes.

15. The equipment of claim 14, wherein the first controller and the plurality of first heat treatment chambers are connected through TO contacts, and the second controller and the plurality of second heat treatment chambers are connected through TO contacts.

16. The equipment of claim 14, wherein the information of the first heat treatment chamber or the second heat treatment chamber being replaced is scanned and stored in the storage server.

17.-20. (canceled)
